(19) United States
(12) Patent Application Publication
(10) Pub. No.: US 2016/0289458 A1
(43) Pub. Date: Oct. 6, 2016

(54) Hydrophobic Phosphonate and Silane Chemistry

(71) Applicant: Moxtek, Inc., Orem, UT (US)

(72) Inventors: Matt Linford, Orem, UT (US); Anubhav Diwan, Provo, UT (US); Fred Lane, Salt Lake City, UT (US)

(21) Appl. No.: 15/078,753

(22) Filed: Mar. 23, 2016

Related U.S. Application Data
(60) Provisional application No. 62/142,854, filed on Apr. 3, 2015.
(60) Provisional application No. 62/190,188, filed on Jul. 8, 2015.
(60) Provisional application No. 62/216,782, filed on Sep. 10, 2015.
(60) Provisional application No. 62/209,024, filed on Aug. 24, 2015.
(60) Provisional application No. 62/242,883, filed on Oct. 16, 2015.
(60) Provisional application No. 62/265,773, filed on Dec. 10, 2015.

(51) Int. Cl. C09D 5/08; C23C 16/24

(52) U.S. Cl. CPC C09D 5/08; C23C 16/24

(57) ABSTRACT

Embodiments of a chemical, methods of applying a chemical, and devices with a coating of a chemical can be used to protect devices from harm, such as for example corrosion, water tensile forces, dust, and oxidation. The device can include a phosphonate-coating, a silane-coating, or both, located on a substrate. The silane-coating can include chemical formula (1), chemical formula (2), or combinations thereof; and the phosphonate-coating can include chemical formula (3):

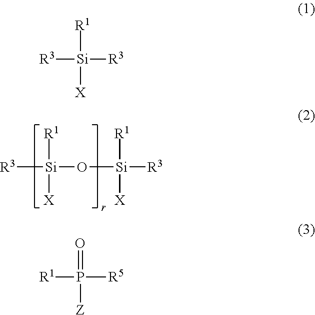

where R¹ can be a hydrophobic group; R³ and R⁵ can be any chemical element or group; r can be a positive integer; and X and Z can each be a bond to the substrate.

### CLAIM OF PRIORITY

This claims priority to U.S. Provisional Patent Application No. 62/142,854, filed on Apr. 3, 2015; 62/190,188, filed on Jul. 8, 2015; 62/216,782, filed on Sep. 10, 2015; 62/209,024, filed on Aug. 24, 2015; 62/242,883, filed on Oct. 16, 2015; and 62/265,773, filed on Dec. 10, 2015, which are hereby incorporated herein by reference in their entirety.

### FIELD OF THE INVENTION

The present application is related generally to hydrophobic chemistry.

### BACKGROUND

Water corrosion can be a substantial problem for many different types of devices. On devices with small features (e.g. nanometer-sized), water tensile forces can cause the small features to topple-over, thus destroying or degrading the functionality of the device. Dust and/or oxidation can interfere with proper performance of some devices (e.g. optics). It would be beneficial to provide protection to such devices from corrosion, water tensile forces, dust, and oxidation.

### SUMMARY

It has been recognized that it would be advantageous to protect devices from corrosion, water tensile forces, dust, and oxidation. The present invention is directed to embodiments of a chemical, methods of applying a chemical, and devices with a coating of a chemical, which can be used to satisfy these needs. Each embodiment may satisfy one, some, or all of these needs.

The chemical can include a phosphonate chemical comprising (R¹)ᵢPO(R⁴)ⱼ(R⁵)ₖ. The method can comprise applying a phosphonate chemical, applying a silane chemical, or both, onto a substrate of a device by vapor deposition. The phosphonate chemical can include (R¹)ᵢPO(R⁴)ⱼ(R⁵)ₖ and the silane chemical can include Si(R¹)_{d}(R²)ₑ(R³)_{g}.

The device can comprise a phosphonate-coating, a silane-coating, or both, located on a substrate. The silane-coating can include chemical formula (1), chemical formula (2), or combinations thereof; and the phosphonate-coating can include chemical formula (3):

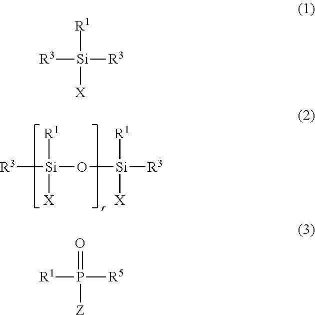

For the above chemical, method, and device:
each R¹ independently can be a hydrophobic group;
R² can be a silane-reactive-group and each silane-reactive-group can be independently selected from: —Cl, —OR⁶, —OCOR⁶, —N(R⁶)₂, and —OH;
each R³ and each R⁵, if any, can be independently any chemical element or group.
R⁴ can be a phosphonate-reactive-group and each phosphonate-reactive-group can be independently selected from: —Cl, —OR⁶, —OCOR⁶, and —OH;
each R⁶ can be independently an alkyl group, an aryl group, or combinations thereof;
d can be 1, 2, or 3, e can be 1, 2, or 3, g can be 0, 1, or 2, and d+e+g=4;
i can be 1 or 2, j can be 1 or 2, k can be 0 or 1, and i+j+k=3;
r can be a positive integer; and
X and Z can each be a bond to the substrate.

### BRIEF DESCRIPTION OF THE DRAWINGS

FIG. 1 is a schematic cross-sectional side view of a device 10, with a coating 13 comprising a proximal coating 13ₚ, a middle coating 13ₘ, and a distal coating 13_{d}, located on a substrate 11, in accordance with an embodiment of the present invention.

FIG. 2 is a schematic cross-sectional side view of a device 20, including a plurality of protrusions 14 extending outwards from the substrate 11, gaps G between the protrusions 14, and a coating 13 that is a conformal-coating, in accordance with an embodiment of the present invention.

FIG. 3 is a schematic cross-sectional side view of a device 30, similar to device 20, but with two layers in the coating 13, including a proximal coating 13ₚ and a distal coating 13_{d}, both of which coatings 13 are conformal-coatings, in accordance with an embodiment of the present invention.

FIG. 4 is a schematic cross-sectional side view of a device 40, similar to devices 20 and 30, but with three layers in the coating 13, including a proximal coating 13ₚ, a middle coating 13ₘ, and a distal coating 13_{d}, all of which coatings 13 are conformal-coatings, in accordance with an embodiment of the present invention.

FIG. 5 is a schematic cross-sectional side view of a device 50, with a substrate 11 divided into different regions 11_{b}, 51, and 55, a coating 53 with one chemistry preferentially attaching to one region 51, and a coating 54 with a different chemistry preferentially attaching to other regions 55 and 11_{b}, in accordance with an embodiment of the present invention.

FIG. 6 is a schematic cross-sectional side view of a device 60, including a plurality of protrusions 14 extending outwards from the substrate 11, gaps G between the protrusions 14, and a coating 13 that includes a hydrophobic-layer, designed to keep water 61, on a surface of the protrusions 14, in a Cassie-Baxter state, in accordance with an embodiment of the present invention.

### DEFINITIONS

As used herein, “alkyl” refers to a branched, unbranched, or cyclic saturated hydrocarbon group. Alkyls include, but are not limited to, methyl, ethyl, n-propyl, isopropyl, n-butyl, isobutyl, t-butyl, octyl, and decyl, for example, as well as cycloalkyl groups such as cyclopentyl, and cyclohexyl, for example. As used herein, “substituted alkyl” refers to an alkyl substituted with one or more substituent groups. The term “heteroalkyl” refers to an alkyl in which at least one carbon atom is replaced with a heteroatom. If not otherwise indicated, the term “alkyl” includes unsubstituted alkyl, substituted alkyl, and heteroalkyl. The “alkyl” can be relatively small, if overall atomic weight of the molecule is desired, such as for example ≦2 carbon atoms in one aspect, ≦3 carbon atoms in another aspect, ≦5 carbon atoms in another aspect, or ≦10 carbon atoms in another aspect.

As used herein, “aryl” refers to a group containing a single aromatic ring or multiple aromatic rings that are fused together, directly linked, or indirectly linked (such that the different aromatic rings are bound to a common group such as a methylene or ethylene moiety). Aryl groups include, for example, phenyl, naphthyl, anthryl, phenanthryl, biphenyl, diphenylether, diphenylamine, and benzophenone. The term “substituted aryl” refers to an aryl group comprising one or more substituent groups. The term “heteroaryl” refers to an aryl group in which at least one carbon atom is replaced with a heteroatom. If not otherwise indicated, the term “aryl” includes unsubstituted aryl, substituted aryl, and heteroaryl.

As used herein, the phrases “bond to the substrate” and “bond to the protrusions” or similar phrases (e.g. “Z is a bond to the substrate”) can mean a direct bond between the chemical and the substrate/protrusions or a bond to an intermediate layer which is bonded directly, or through other layer(s) to the substrate/protrusions. These layer(s) can be other coating(s).

As used herein, the term “carbon chain” means a chain of carbon atoms linked together, including at least three carbon atoms in a row (e.g. —C—C—C—, —C═C—C—, etc.). The term carbon chain can include at least five carbon atoms in a row in one aspect, at least ten carbon atoms in a row in another aspect, or at least fifteen carbon atoms in a row in another aspect. The term carbon chain can also include ether linkages (C—O—C moieties). The term carbon chain includes single, double, and triple carbon to carbon bonds. The carbon atoms can be attached to any element or molecule.

As used herein, the term “conformal-coating” on a device means a coating that follows or conforms to contours of the device.

As used herein, the unit “sccm” means cubic centimeters per minute at 0° C. and 1 atmosphere pressure.

As used herein, the term “substrate” includes base-portion 11_{b} of the device, and protrusions 14, if any, but does not include the protective coating 13.

### DETAILED DESCRIPTION

### Chemical

A silane chemical can have chemical formula: Si(R¹)_{d}(R²)ₑ(R³)_{g}, and a phosphonate chemical can have chemical formula: (R¹)ᵢPO(R⁴)ⱼ(R⁵)ₖ, where:
1. d is 1, 2, or 3, e is 1, 2, or 3, g is 0, 1, or 2, and d+e+g=4;
2. i is 1 or 2, j is 1 or 2, k is 0 or 1, and i+j+k=3;
3. each R¹ can independently a hydrophobic group, and thus the chemical can be used to repel water;
4. R² is a silane-reactive-group and each silane-reactive-group is independently selected from: —Cl, —OR⁶, —OCOR⁶, —N(R⁶)₂, and —OH;
5. R⁴ is a phosphonate-reactive-group and each phosphonate-reactive-group is independently selected from: —Cl, —OR⁶, —OCOR⁶, and —OH;
6. each R³ and each R⁵, if any, is independently any chemical element or group, and
7. each R⁶ is independently an alkyl group, an aryl group, or combinations thereof.
   Additional details of these chemicals are described below.

These chemicals (silane and phosphonate) can be used to protect devices from corrosion, water tensile forces, and dust. These chemicals can be particularly useful to protect metal oxides, and can generally adhere well to most metal oxides, such as for example aluminum oxide, zirconium oxide, and hafnium oxide. These chemicals can improve zirconium's and hafnium's corrosion-resistance by minimizing contact-time of water with the surface. These chemicals can adhere to sapphire and metal surfaces of watches, tablets, cell-phones, and phablets. These chemicals can also adhere to devices made of iron and stainless steel.

If a substrate, of the device to be protected, includes a surface that these chemicals do not bond to, an intermediate layer (e.g. a barrier-layer of a silicon dioxide conformal-coating, described below) can first be deposited on the substrate 11, then the chemical may be deposited.

### Device

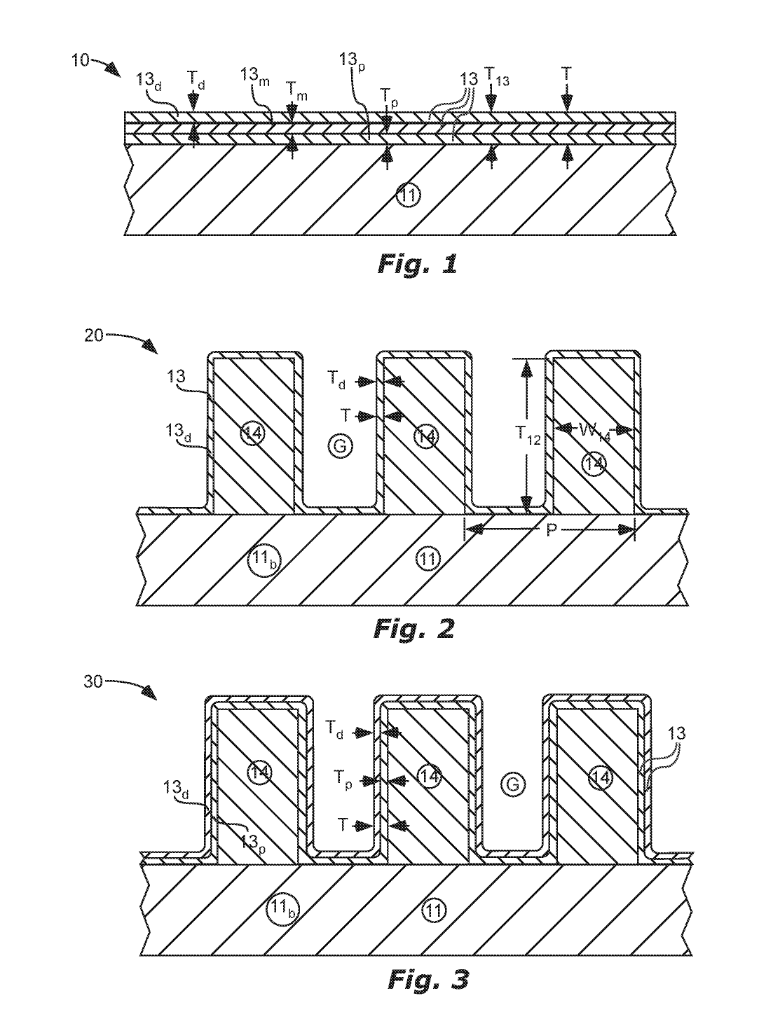

Shown in FIGS. 1-6, are devices 10, 20, 30, 40, 50, and 60, each comprising a coating 13 located on a substrate 11. The coating 13 can include layer, or both, which will be described below.

The coating 13 can include a single layer (FIG. 2) or multiple, different layers (see FIGS. 1, and 3-4). The coating 13 can include at least one of: a proximal coating 13ₚ, a middle coating 13ₘ, and a distal coating 13_{d}. It can be important to have a sufficiently large thickness Tₚ, Tₘ, and T_{d} for each of these layers 13ₚ, 13ₘ, and 13_{d}, respectively, or a sufficiently large thickness T of all layers combined, of the coating 13, in order to provide sufficient protection to the substrate 11 and/or to provide a base for an upper layer of the coating 13. Thus, one or more of the proximal coating 13ₚ, the middle coating 13ₘ, and the distal coating 13_{d} can have a thickness Tₚ, Tₘ, or T_{d}, or all layers combined can have a thickness T, that is at least 0.1 in one aspect, at least 0.5 nanometers in another aspect, or at least 1 nanometer in another aspect.

It can be important to have a sufficiently small thickness Tₚ, Tₘ, and T_{d} for each of these layers 13ₚ, 13ₘ, and 13_{d}, respectively, or a sufficiently small thickness T of all layers combined, of the coating 13, in order to (1) avoid unnecessary chemical expense and/or (2) to avoid or minimize degradation of device performance caused by the coating 13 (e.g. an excessively thick coating can interfere with transmission of light in an optical device). Thus, one or more of the proximal coating 13ₚ, the middle coating 13ₘ, and the distal coating 13_{d}, can have a thickness Tₚ, Tₘ, or T_{d}, or all layers combined can have a thickness T, that is less than 2 nanometers in one aspect, less than 3 nanometers in another aspect, less than 5 nanometers in another aspect, less than 10 nanometers in another aspect, less than 15 nanometers in another aspect, or less than 20 nanometers in another aspect.

These thickness values can be a minimum thickness or a maximum thickness at any location of the coating 13, or simply a thickness at a specific location of the coating 13. Each layer of the coating 13 can be a monolayer.

The coating 13 can provide protection from corrosion and dust, and can minimize stiction, for many types of substrates 11. For example, the substrate 11 can be a micro-electro-mechanical (MEMS) device. Water can corrode a MEMS device or can cause components to stick together. The coating 13 can be hydrophobic to avoid water remaining on the surface of the MEMS device. Thus, the coating 13 can provide corrosion and anti-stiction protection.

The substrate 11 can be a watch, tablet, phablet, or cell-phone and the coating 13 can provide corrosion protection to these devices. The substrate 11 can be an optical device (a device that creates, manipulates, or measures electromagnetic radiation), such as a for example a lens, an optical sensor, or a polarizer. The coating 13 can be hydrophobic, can protect the optical device from corrosion, and dust can be automatically removed as water rolls off the coating 13.

The substrate 11 can be a vacuum chamber; the coating 13 can be hydrophobic and can prevent or limit adsorption of water contaminants on its walls. The substrate 11 can be a mechanical device, such as car or engine parts, and the coating 13 can provide corrosion protection.

The substrate 11 can be an electronic component or electronic circuitry. The coating 13 can protect the electronic component or circuitry from corrosion and can cause water (which otherwise could cause a short-circuit) to roll off of a surface of the electronic circuit.

The coating 13 can protect against galvanic/voltaic corrosion by insulating metal surfaces against water. The coating can be used to protect heat exchangers, particularly heat exchangers that include water on at least one side.

As shown in FIGS. 2-6, the substrate 11 can include a plurality of protrusions 14 extending outwards from a base-portion 11_{b} of the substrate 11. The protrusions 14 can have various shapes, such as ribs or posts for example. There can be gaps G between the protrusions 14. The gaps G can be filled with air, vacuum, or some other material. The coating 13 can be a conformal-coating, and thus can conform to a surface of, and can coat or substantially cover, the protrusions 14 and any exposed surface of the substrate 11 (“exposed surface” meaning a surface of the substrate 11 not covered with protrusions 14).

The protrusions 14 can have a small pitch P (see FIG. 2), such as for example less than 200 nanometers in one aspect or less than 150 nanometers in another aspect. The protrusions 14 can have a small width W₁₄, such as for example less than 150 nanometers in one aspect or less than 100 nanometers in another aspect. The protrusions 14 can have a small thickness T₁₂, such as for example less than 1000 nanometers in one aspect, less than 500 nanometers in another aspect, or less than 100 nanometers in another aspect.

For example, wire grid polarizers can have protrusions 14 or wires that are rib-shaped. As another example, optical sensors can have protrusions 14 that are post-shaped, or can have an array of holes separated by an intersecting grid of protrusions 14. One use of such optical sensors is chemical analysis. A chemical, which can have a very small concentration in a sample, can be detected by plasmonic resonance in such holes. For proper performance of such devices, it can be important for the protrusions 14 to be small (e.g. nanometer-sized or micrometer-sized and consequently fragile). Also, optimal materials for these protrusions 14 can be materials that are susceptible to corrosion (e.g. aluminum). The coating 13 can provide protection for such devices by reducing water tensile forces on the protrusions 14 and by minimizing water contact, and thus minimizing corrosion.

### Hydrophobic-Layer Description

The coating 13 can include a hydrophobic-layer. The hydrophobic-layer can include a phosphonate coating, which can include:

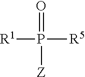

where each R¹ can independently be a hydrophobic group, Z can be a bond to the substrate 11, and R⁵ can be any chemical element or group. R⁵ can be a phosphonate-reactive-group, R¹, or R⁶. The phosphonate-reactive-group can be a chemical element or group likely to react to form an additional bond Z to the ribs 12, such as for example —Cl, —OR⁶, —OCOR⁶, or —OH. Each R⁶ can independently be an alkyl group, an aryl group, or combinations thereof.

The hydrophobic-layer can alternatively or in addition include a silane coating, which can include chemical formula (1), chemical formula (2), or combinations thereof:

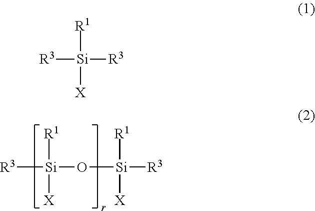

where r can be a positive integer, X can be a bond to the substrate 11, and each R³ can be independently a chemical element or a group. Each R¹, as mentioned above, can independently be a hydrophobic group.

Each R³ can be independently selected from the group consisting of: a silane-reactive-group, —H, R¹, and R⁶. R⁶ was defined above. Each silane-reactive-group can be independently selected from the group consisting of: —Cl, —OR⁶, —OCOR⁶, —N(R⁶)₂, and —OH.

R³ and/or R⁵ can be a small group, such as for example —OCH₃, to allow easier vapor-deposition. Benefits of vapor-deposition are described below.

The hydrophobic-layer can alternatively or in addition include a sulfur coating, which can include:

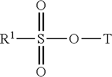

where T can be a bond to the substrate and each R¹, as mentioned above, can independently be a hydrophobic group.

As shown on device 50 in FIG. 5, the substrate can include different regions 51, 55, and 11. Each protrusion 14 can include multiple regions 51 and 55. Each region 51, 55, and 11 can be made of different materials. It can be difficult to protect these different regions 51, 55, and 11 that are made of different materials because protective chemistry that adheres well to one material might not adhere well to another. At least two of the silane coating, the phosphonate coating, and the sulfur coating can be applied to the device 50. One of these coatings can preferentially adhere to one region and another can preferentially adhere to another region, thus providing effective protection to both.

For example, in a selectively-absorptive wire grid polarizer, the protrusions 14 can be ribs with an upper-region 51 and a lower-region 55. The lower-region 55 can be reflective (e.g. aluminum for visible light), the upper-region 51 can be absorptive (e.g. silicon for visible light), and the base-portion 11_{b} of the substrate 11 can be transparent (e.g. glass). The silane coating can be coating 53, preferentially-adhering to the silicon upper-region 51. The phosphonate coating can be coating 54, preferentially-adhering to the aluminum lower-region 55.

Money can be saved by using the phosphonate chemistry and the silane chemistry instead of just the silane chemistry because the phosphonate chemistry is presently less expensive than the silane chemistry. Thus, by combining the silane with the phosphonate, less of the expensive silane chemistry is needed.

For example, at least one region of the substrate 11 can include much more silane-coating than phosphonate-coating (e.g. coating 53 on region 51 compared to coating 54 on regions 55 and 11_{b}), such as at least two times more in one aspect, at least three times more in another aspect, at least five times more in another aspect, or at least ten times more in another aspect. Another region of the substrate 11 can include much more phosphonate-coating than silane-coating (e.g. coating 54 on regions 55 and 11_{b} compared to coating 53 on region 51), such as at least two times more in one aspect, at least three times more in another aspect, at least five times more in another aspect, or at least ten times more in another aspect.

X (a bond to the substrate 11 in the silane coating) can be —O—Si. For example, the material of the region of the substrate 11 where the silane coating preferentially bonds can be silicon or silicon dioxide. Z (a bond to the substrate 11 in the phosphonate coating) can be —O-Metal, where Metal is a metal atom. For example, Metal can be aluminum.

It can be beneficial if the chemicals in the hydrophobic-layer include molecules that each has multiple bonds T, Z, and/or X to the ribs 12. By each molecule forming multiple bonds X, more of the underlying surface (e.g. rib 12, proximal coating 13ₚ, or middle coating 13ₘ) can be bound and thus unavailable for bonding or interaction with undesirable chemicals, such as water for example. Also, multiple bonds to the surface can improve resiliency of the hydrophobic-layer because it can be less likely for multiple bonds Z/X/T to fail than for a single bond Z/X/T to fail.

Thus, R¹ can be:

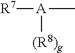

where A is a central atom, R⁷ can be a hydrophobic group as described above, g can be an integer from 1 to 3, and R⁸ can be moiety (1), moiety (2), moiety (3), or combinations thereof:

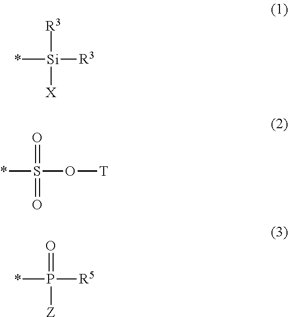

R³ and R⁵ were described above. The central atom A can be selected from group III, IV, or V in the periodic table in one aspect or can be selected from the group consisting of carbon, nitrogen, phosphorus, and silicon in another aspect.

For example, for g=2, the phosphonate coating, and moiety (3), the resulting chemical formula can be:

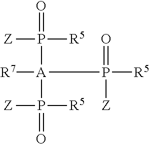

Another way for molecules in the hydrophobic-layer to form multiple bonds Z, and/or X to the ribs 12 is for R⁵ to be Z and/or for R³ to be X. This can be accomplished if in the phosphonate chemistry as applied, R⁵ is a phosphonate-reactive-group and/or if, in the silane chemistry as applied, R³ is a silane-reactive-group.

The hydrophobic group can be or can include a carbon chain in one aspect or at least one halogen bonded to a carbon in another aspect. The carbon chain can include a perfluorinated group including at least 1 carbon atom in one aspect or at least 3 carbon atoms in another aspect. The perfluorinated group can include less than 20 carbon atoms in another aspect, less than 30 carbon atoms in another aspect, or less than 40 carbon atoms in another aspect. It can be beneficial for the perfluorinated group to have at least 4 carbon atoms to provide a hydrophobic chain. It can be beneficial for the perfluorinated group to not be too long or have too many carbon atoms in order to maintain a high enough vapor pressure to allow vapor-deposition.

For example, the carbon chain of R¹ can include CF₃(CF₂)ₙ. Due to the high electronegativity of fluorine, it can be beneficial to have a hydrocarbon chain to separate the perfluorinated group from the phosphorus, sulfur, or silicon. Thus, the carbon chain of R¹ can include CF₃(CF₂)ₙ(CH₂)ₘ, where n can be an integer within the boundaries of 0≦n≦20 in one aspect or 4≦n≦10 in another aspect, and m can be an integer within the boundaries of 0≦m≦5 in one aspect or 2≦m≦5 in another aspect.

In order to allow vapor-deposition, it can be important for some or all of the conformal-coating chemistry to have a relatively lower molecular weight, but it can also be important for the carbon chain to be long enough to provide sufficient hydrophobicity. Thus, each molecule in the phosphonate coating (excluding the bond to the substrate Z), each molecule in the silane coating (excluding the bond to the substrate X), and/or each molecule in the sulfur coating (excluding the bond to the substrate T), can have a molecular weight of at least 100 grams per mole in one aspect, at least 150 grams per mole in another aspect, or at least 400 grams per mole in another aspect, and less than 600 grams per mole in one aspect, less than 1000 grams per mole in another aspect, or less than 1500 grams per mole in another aspect.

In the hydrophobic-layer, it can be important to have a strong bond between silicon (Si) and R¹, between phosphorus (P) and R¹, and/or between sulfur (S) and R¹, to avoid the R¹ group breaking away from Si, P, or S. Thus, the bond between silicon (Si) and R¹ can be a silicon to carbon bond (Si—C); the bond between phosphorus (P) and R¹ can be a phosphorus to carbon bond (P—C); and/or the bond between sulfur (S) and R¹ can be a sulfur to carbon bond (S—C).

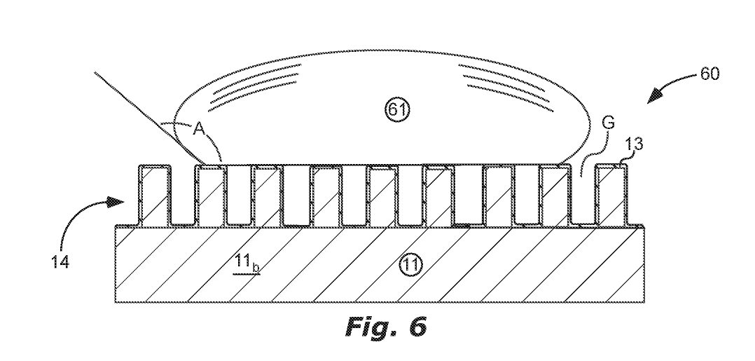

The hydrophobic-layer located on the protrusions 14 can provide a hydrophobic surface, which can be a superhydrophobic surface, depending on the chemistry and the structure of the protrusions 14, such as pitch P and protrusion width W₁₄ (see FIG. 2). As shown in FIG. 6, the device 60 and hydrophobic-layer 13 can be capable of keeping water 61, on a surface of the protrusions 14, in a Cassie-Baxter state. Having water on the device 60 in a Cassie-Baxter state can be beneficial because the water 61 does not substantially enter or remain in the gaps G, thus avoiding or reducing corrosion on sides of the protrusions 14 and avoiding or reducing toppling of the protrusions 14 due to water's tensile forces. Also, if the water 61 is in a Cassie-Baxter state, the water 61 can more easily roll off the surface of the device 60, often carrying dust particles with it. A water contact angle A can be greater than 110° in one aspect, greater than 120° in another aspect, greater than 130° in another aspect, or greater than 140° in another aspect.

### Soluble Device Materials

It can be beneficial to use materials in the devices 10, 20, 30, 40, 50, and 60 that have relatively high water-solubility. Germanium, for example, is a material that is useful in wire grid polarizers, but germanium has a soluble oxide (about 4.5 g/L at 25° C.). This solubility can be a problem, not only during use of, but also during manufacture of the device 10, 20, 30, 40, 50, or 60. For example, protective coatings, such as amino phosphonate, are applied to wire grid polarizers by immersion in an aqueous solution of amino phosphonate (see U.S. Pat. No. 6,785,050). Germanium oxide can be dissolved during application of the amino phosphonate.

Partial dissolution of the germanium, or other water-soluble material, can be avoided by applying the coating 13 by anhydrous-immersion and/or by vapor-deposition. For example, an anhydrous method can be helpful if a material of an exterior of the ribs 12 has solubility in water of at least 0.015 grams per liter at 25° C. in one aspect, at least 0.02 grams per liter at 25° C. in another aspect, at least 0.05 grams per liter at 25° C. in another aspect, at least 0.5 grams per liter at 25° C. in another aspect, at least 1 gram per liter at 25° C. in another aspect, at least 2 grams per liter at 25° C. in another aspect, or at least 4 grams per liter at 25° C. in another aspect.

Non-limiting examples of vapor-deposition methods include chemical vapor-deposition (CVD), low-pressure CVD (LPCVD), plasma-enhanced CVD, physical vapor-deposition (PVD), atomic layer deposition (ALD), thermoreactive diffusion, electron-beam deposition, sputtering, and thermal evaporation. Anhydrous-immersion can include submersion of the device in an anhydrous, liquid bath. A solvent that will not dissolve substrate 11 materials can be selected. Vapor-deposition can be preferred over immersion because of reduced process-waste disposal problems, reduced health hazards, reduced or no undesirable residue from rinsing, and vapor-deposition can be done with standard semiconductor processing equipment.

The oxidation-barrier and the moisture-barrier described below can be applied by ALD. Some embodiments of the hydrophobic-layer have a sufficiently-high vapor pressure and can be applied by vapor-deposition.

### Oxidation-Barrier and Moisture-Barrier

The coating 13 can include a barrier-layer. The barrier-layer can include an oxidation-barrier, a moisture-barrier, or both. The barrier-layer can include a metal oxide, or layers of different metal oxides.

Oxidation can be harmful to some devices, such as oxidation of aluminum of a wire grid polarizer for example. An oxidation-barrier can reduce oxidation of the device. The term “oxidation-barrier” means a first material capable of reducing the ingress of oxygen into a second material, which may cause the second material to oxidize. Examples of chemicals that can be used as an oxidation-barrier include, but are not limited to: aluminum oxide, silicon oxide, silicon nitride, silicon oxynitride, silicon carbide, or combinations thereof.

Corrosion can degrade device performance. For example, in a wire grid polarizer, water can condense onto the polarizer and wick into narrow channels between ribs due to capillary action. The water can then corrode the ribs.

Corroded regions can have reduced performance, or can fail to polarize at all. A moisture-barrier can resist corrosion. A moisture-barrier can protect the device 10, 20, 30, 40, 50, or 60, and especially protrusions 14 of the device 20, 30, 40, 50, or 60 from water or other corrosion. Examples of chemicals that can be used as a moisture-barrier include: hafnium oxide, zirconium oxide, or combinations thereof.

The barrier-layer can include rare earth oxides, for example, oxides of scandium, yttrium, lanthanum, cerium, praseodymium, neodymium, promethium, samarium, europium, gadolinium, terbium, dysprosium, holmium, erbium, thulium, ytterbium, and lutetium. These rare earth oxides can be at least part of the oxidation-barrier, the moisture-barrier, or both.

The barrier-layer can be distinct from the substrate 11, meaning (1) there can be a boundary line or layer between the substrate 11 and the barrier-layer; or (2) there can be some difference of material of the barrier-layer relative to a material of the substrate 11. For example, a native aluminum oxide can form at a surface of aluminum. A layer of aluminum oxide (oxidation-barrier) can then be applied to the aluminum (e.g. by ALD). This added layer of aluminum oxide can be important, because a thickness and/or density of the native aluminum oxide can be insufficient for protecting a core of the aluminum (e.g. substantially pure aluminum) from oxidizing. In this example, although the oxidation-barrier (Al₂O₃) has the same material composition a surface (Al₂O₃) of the device, the oxidation-barrier can still be distinct due to (1) a boundary layer between the oxidation-barrier and the device and/or (2) a difference in material properties, such as an increased density of the oxidation-barrier relative to the native aluminum oxide.

### Silicon Dioxide Conformal-Coating

A silicon dioxide conformal-coating can be located between the silane coating and the substrate 11. The silicon dioxide conformal-coating can help the silane coating bond to the substrate 11. The silicon dioxide conformal-coating can be the proximal coating 13ₚ or the middle coating 13ₘ, or an additional layer of the coating 13 located between the middle coating 13ₘ and the distal coating 13_{d}.

### Multiple Conformal-Coatings

The oxidation-barrier can be less effective at resisting corrosion. The moisture-barrier and/or hydrophobic-layer can be less effective at resisting oxidation. Thus, it can be beneficial to combine both an oxidation-barrier with a moisture-barrier and/or hydrophobic-layer.

Although the moisture-barrier can resist corrosion, it can eventually break down. Thus, it can be beneficial to minimize exposure of the moisture-barrier to water. A hydrophobic-layer can minimize or prevent condensed water on the device from attacking the moisture-barrier, thus extending the life of the moisture-barrier and the device. If the hydrophobic-layer perfectly covers the substrate 11, and never breaks down, then a moisture-barrier might not be needed. But, due to imperfections in manufacturing, there can be locations on the substrate 11 that are not covered, or less densely covered, by the hydrophobic-layer. The moisture-barrier can provide protection to these locations. Also, the hydrophobic-layer can break down over time. The moisture-barrier can provide protection after such breakdown. Therefore, it can be beneficial to combine both a moisture-barrier and a hydrophobic-layer.

If the hydrophobic-layer keeps water on the protrusions 14 in a Cassie-Baxter state (see FIG. 6), then protrusion 14 damage, which could otherwise be caused by tensile forces in water in the gaps G, can be avoided. Also, the water can roll off the surface of the device 60, often carrying dust particles with it, in a self-cleaning fashion. These are added benefits of the hydrophobic-layer that might not be provided by the oxidation-barrier or the moisture-barrier.

Thus, it can be beneficial for improved device protection and/or for improved adhesion of an upper-layer of the coating 13, for the coating 13 to have multiple layers, which can include at least two of: an oxidation-barrier, a moisture-barrier, a silicon dioxide conformal-coating, and a hydrophobic-layer. This added protection, however, is not free. Each additional layer in the coating 13 can increase device cost, especially if more than one tool is required to apply the multiple layers of the coating 13. Thus, a determination of the number of layers in the conformal-coatings 13 can be made by weighing cost against needed protection.

Device 20 in FIG. 2 includes a coating 13 with one layer: a distal coating 13_{d}. The distal coating 13_{d} can be the oxidation-barrier, the moisture-barrier, or the hydrophobic-layer.

Device 30 in FIG. 3 includes a coating 13 with two layers: a proximal coating 13ₚ located closer to the protrusions 14 and substrate 11 and a distal coating 13_{d} located over the proximal coating 13ₚ. The proximal coating 13ₚ and the distal coating 13_{d} can comprise oxidation-barrier(s), moisture-barrier(s), and/or hydrophobic-layer(s).

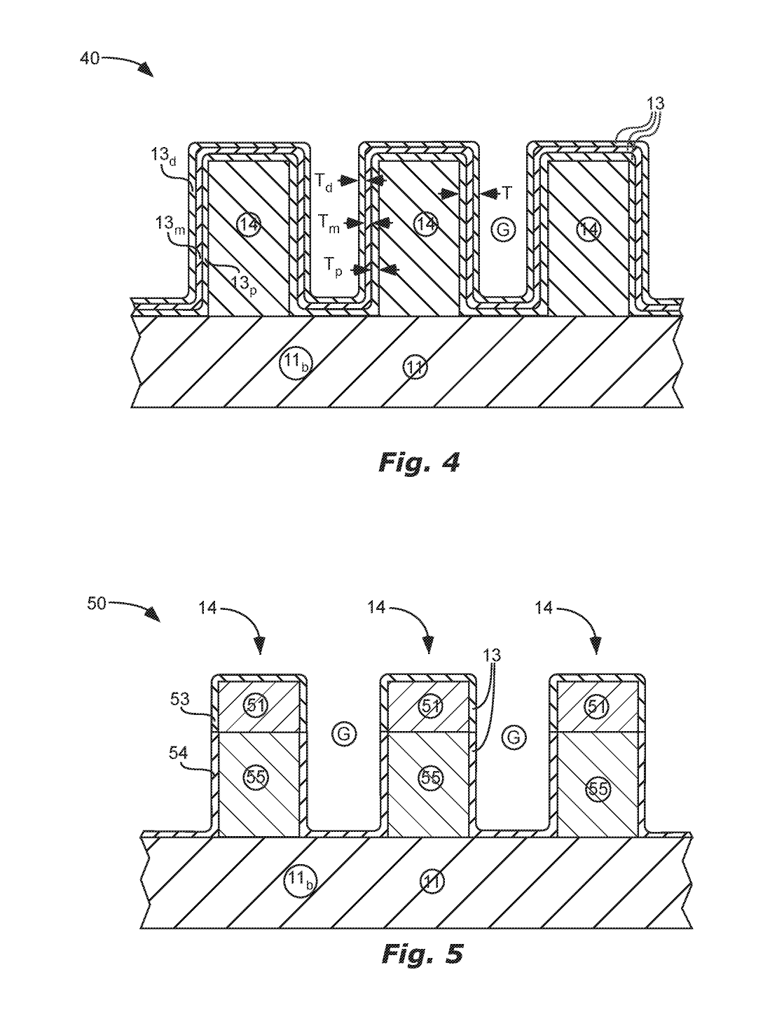

Devices 10 and 40 in FIGS. 1 and 4, respectively, include a coating 13 with three layers: the proximal coating 13ₚ, the distal coating 13_{d}, and a middle coating 13ₘ located between the proximal coating 13ₚ and the distal coating 13_{d}. The proximal coating 13ₚ, the middle coating 13ₘ, and the distal coating 13_{d} can comprise oxidation-barrier(s), moisture-barrier(s), and/or hydrophobic-layer(s). Although not shown in the figures, there can be more than three layers in the coating 13.

### Order of Conformal-Coating Layers

It can be beneficial to use the moisture-barrier over the oxidation-barrier (i.e. the oxidation-barrier is proximal and the moisture-barrier is distal or middle), thus the moisture-barrier can provide corrosion protection to the oxidation-barrier. The oxidation-barrier can provide a good substrate for deposition of the moisture-barrier, resulting in a less porous moisture-barrier. Thus, the same moisture protection may be obtained by a relatively thinner moisture-barrier. This can be important because the moisture-barrier can degrade device performance, but such degradation can be minimized by reduced moisture-barrier thickness. Furthermore, the moisture-barrier can provide an improved surface for attachment of the hydrophobic-layer (if used).

It can be beneficial for the hydrophobic-layer to be located over the barrier-layer (i.e. the hydrophobic-layer can be the distal coating 13_{d}) in order to best keep moisture from entering the gaps G and to minimize or eliminate moisture exposure of the underlying layer(s) in the coating 13 (e.g. the proximal coating 13ₚ and also possibly the middle coating 13ₘ).

### Methods

A method of applying protective chemistry to a device can include some or all of the following steps. The steps can be performed in the order shown, or alternate order:
1. Obtaining the device 10, 20, 30, 40, 50, or 60, which can include a substrate 11, as described above.
2. Exposing the device to ultraviolet light and/or ozone:
   a. This step may be done before applying one or more of the following: a proximal conformal-coating 13ₚ, a middle conformal-coating 13ₘ, and a distal conformal-coating 13_{d}.
   b. Exposing the device to ultraviolet light and ozone can be done sequentially or simultaneously.
   c. Duration of this step can be less than two minutes in one aspect or less than 20 minutes in another aspect.
3. Applying a proximal coating 13ₚ. See FIGS. 1-4.
4. Applying a middle coating 13ₘ. See FIGS. 1 & 4.
5. Plasma cleaning the device.
   a. Plasma cleaning can generate more reactive groups on the surface (i.e. substrate 11, proximal coating 13ₚ, or middle coating 13ₘ), thus improving bonding of the distal coating 13_{d}.
   b. Examples of plasmas include O₂, H₂, Ar, and N₂.
   c. Plasma cleaning can be performed at various temperatures, such as for example between 140° C. and 200° C.
   d. One plasma, used for cleaning the device, included O₂ (flow rate 15 sccm) and H₂ (flow rate 10 sccm) at a power of 400 W for 5 minutes at a temperature of 160° C.
6. Exposing the device 10, 20, 30, 40, 50, or 60 to a gas.
   a. The gas can include water vapor. The water vapor can have a pressure of less than 100 Torr.
   b. This step can increase the number of hydroxyl groups on the underlying surface (e.g. substrate 11, proximal coating 13ₚ, or middle coating 13ₘ), which can improve bonding of phosphonate and/or silane of the hydrophobic-layer.
   c. Duration, pressure, and temperature of this step may need to be carefully limited, depending on the rib structure and the nature of the underlying surface, in order to avoid corrosion.
7. Applying a distal coating 13_{d}.
8. Baking the device. Baking can improve bonding of the hydrophobic-layer.
   a. Baking temperature examples: The device can be baked at greater than between 100° C. in one aspect, greater than 130° C. in another aspect, or greater than 150° C. in another aspect; and less than 300° C. in one aspect, less than 320° C. in another aspect, or less than 400° C. in another aspect.
   b. Baking time examples: The device can be baked for at least 5 minutes, at least 10 minutes in another aspect; and less than 60 minutes in one aspect or less than 90 minutes in another aspect.
   c. Baking at 150° C. for 15 minutes has been successful.

One, two, or every layer of the conformal coating (the proximal coating 13ₚ, the middle coating 13ₘ, and/or the distal coating 13_{d}) can have one or more of the following characteristics:
1. can cover the underlying layer, e.g. an exposed surface of the ribs 12, the proximal coating 13ₚ, or middle coating 13ₚ;
2. can be applied by atomic layer deposition, vapor-deposition, or other anhydrous deposition method;
3. can be applied at an elevated temperature, such as for example at least 300° C. in one aspect, at least 350° C. in another aspect, at least 400° C. in another aspect; and less than 500° C. in one aspect or less than 600° C. in another aspect;
4. can include a metal oxide;
5. can include hafnium oxide, zirconium oxide, aluminum oxide, silicon oxide, silicon nitride, silicon oxynitride, a rare earth oxide, or combinations thereof;
6. can be applied by exposing the device to a silane chemical: Si(R¹)_{d}(R²)ₑ(R³)_{g}, a phosphonate chemical (R¹)ᵢPO(R⁴)ⱼ(R⁵)ₖ, or both, where:
   a. d is 1, 2, or 3, e is 1, 2, or 3, g is 0, 1, or 2, and d+e+g=4;
   b. i is 1 or 2, j is 1 or 2, k is 0 or 1, and i+j+k=3;
   c. each R¹ is independently a hydrophobic group;
   d. R² is a silane-reactive-group and each silane-reactive-group can independently be selected from: —Cl, —OR⁶, —OCOR⁶, —N(R⁶)₂, and —OH;
   e. R⁴ is a phosphonate-reactive-group and each phosphonate-reactive-group can independently be selected from: —Cl, —OR⁶, —OCOR⁶, and —OH;
   f. each R³ and each R⁵, if any, is independently any suitable chemical element or group; and
   g. each R⁶ is independently an alkyl group, an aryl group, or combinations thereof.
      Additional details of the silane chemical and the phosphonate chemical, particularly regarding the hydrophobic group, the phosphonate-reactive-group, the silane-reactive-group, R⁶, R³, R⁵, and molecular weight are described above. The silane chemical and the phosphonate chemical can be applied sequentially or simultaneously.

What is claimed is:

1. A device comprising:
a. a substrate;
a. a phosphonate-coating located on the substrate, wherein the phosphonate-coating includes: 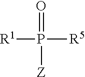
where:
i. each R¹ independently is a hydrophobic group;
ii. Z is a bond to the substrate;
iii. each R⁵ is independently a chemical element or a group.

2. The device of claim 1, wherein at least one R⁵ is —OCH₃.

3. The device of claim 1, wherein:
b. R⁵ is a phosphonate-reactive-group, R¹, R⁶, or Z;
c. the phosphonate-reactive-group is —Cl, —OR⁶, —OCOR⁶, or —OH;
d. each R⁶ is independently an alkyl group, an aryl group, or combinations thereof.

4. The device of claim 1, the hydrophobic group includes CF₃(CF₂)ₙ(CH₂)ₘ, where n and m are integers within the boundaries of: 0≦n≦20 and 0≦m≦5.

5. The device of claim 1, further comprising a silane-coating located on the substrate, wherein the silane-coating includes chemical formula (1), chemical formula (2), or combinations thereof: 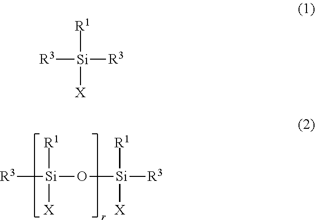
where:
i. r s a positive integer;
ii. X is a bond to the substrate;
iii. each R³ is independently a chemical element or a group.

6. The device of claim 5, wherein at least one R³ is —OCH₃.

7. The device of claim 5, wherein:
a. each R³ is independently selected from the group consisting of: a silane-reactive-group, —H, R¹, R⁶, and X;
b. each silane-reactive-group is independently selected from the group consisting of: —Cl, —OR⁶, —OCOR⁶, —N(R⁶)₂, and —OH; and
c. each R⁶ is independently an alkyl group, an aryl group, or combinations thereof.

8. The device of claim 5, wherein:
a. the substrate includes a plurality of protrusions, and gaps between the protrusions, extending outwards from a base-portion of the substrate;
b. the silane-coating and the phosphonate-coating are conformal-coatings.

9. The device of claim 5, wherein:
a. the substrate includes different regions made of different materials;
b. one region of the substrate includes at least three times more silane-coating than phosphonate-coating; and
c. another region of the substrate includes at least three times more phosphonate-coating than silane-coating.

10. The device of claim 5, wherein:
a. the substrate includes different regions made of different materials;
b. X is —O—Si; and
c. Z is —O-Metal, where Metal s a metal atom.

11. A phosphonate chemical including (R¹)ᵢPO(R⁴)ⱼ(R⁵)ₖ, where:
a. each R¹ independently is a hydrophobic group;
b. i is 1 or 2, j is 1 or 2, k is 0 or 1, and i+j+k=3;
c. R⁴ is a phosphonate-reactive-group;
d. each phosphonate-reactive-group is independently selected from: —Cl, —OR⁶, —OCOR⁶, and —OH;
e. each R⁶ is independently an alkyl group, an aryl group, or combinations thereof; and
f. each R⁵, if any, is independently any chemical element or group.

12. The phosphonate chemical of claim 11, wherein the phosphonate chemical has a molecular weight between 400 and 600 grams per mole.

13. A method of applying protective chemistry to a device, the method comprising applying a phosphonate chemical onto a substrate of the device by vapor deposition, wherein the chemical includes (R¹)ᵢPO(R⁴)ⱼ(R⁵)ₖ, where:
a. each R¹ independently is a hydrophobic group;
a. i is 1 or 2, j is 1 or 2, k is 0 or 1, and i+j+k=3;
b. R⁴ is a phosphonate-reactive-group and each phosphonate-reactive-group is independently selected from: —Cl, —OR⁶, —OCOR⁶, and —OH;
c. each R⁶ is independently an alkyl group, an aryl group, or combinations thereof; and
d. each R⁵, if any, is independently any chemical element or group.

14. The method of claim 13, wherein the phosphonate chemical has a molecular weight between 400 and 600 grams per mole.

15. The method of claim 13, wherein:
a. R⁵ is a phosphonate-reactive-group, R¹, R⁶, or Z; and
b. the phosphonate-reactive-group is —Cl, —OR⁶, —OCOR⁶, or —OH.

16. The method of claim 13, further comprising exposing the device to a gas before applying the phosphonate chemical, wherein the gas includes water vapor and the water vapor has a pressure of less than 100 Torr.

17. The method of claim 13, further comprising baking the device after applying the phosphonate chemical, wherein baking the device occurs at a temperature between 100° C. and 320° C. for between 5 and 90 minutes.

18. The method of claim 13, further comprising plasma cleaning the device, at a temperature between 140° C. and 200° C., before applying the phosphonate chemical.

19. The method of claim 13, further comprising applying a silane chemical onto the substrate by vapor deposition, wherein the silane chemical includes Si(R¹)_{d}(R²)ₑ(R³)_{g} where:
a. d is 1, 2, or 3, e is 1, 2, or 3, g is 0, 1, or 2, and d+e+g=4;
b. R² is a silane-reactive-group;
c. each silane-reactive-group is independently selected from: —Cl, —OR⁶, —OCOR⁶, —N(R⁶)₂, and —OH; and
d. each R³, if any, is independently any chemical element or group.

20. The method of claim 19, wherein:
a. each R³ is independently selected from the group consisting of: a silane-reactive-group, —H, R¹, R⁶, and X; and
b. each silane-reactive-group is independently selected from the group consisting of: —Cl, —OR⁶, —OCOR⁶, —N(R⁶)₂, and —OH.
